(19) United States
(12) Patent Application Publication
(10) Pub. No.: US 2026/0164716 A1
(43) Pub. Date: Jun. 11, 2026

(54) BACKSIDE DIFFUSION BREAK WITH GATE ACCESS

(71) Applicant: International Business Machines Corporation, Armonk, NY (US)

(72) Inventors: Sagarika Mukesh, Albany, NY (US); Ruilong Xie, Niskayuna, NY (US); Tao Li, Slingerlands, NY (US); Wai Kin Li, Albany, NY (US); Albert Manhee Chu, Nashua, NH (US); Jingyun Zhang, Albany, NY (US)

(21) Appl. No.: 18/977,054

(22) Filed: Dec. 11, 2024

(51) Int. Cl. H10D 30/67; H10D 30/00; H10D 30/01; H10D 62/10; H10D 84/85

(52) U.S. Cl. CPC H10D 30/6729; H10D 30/019; H10D 30/507; H10D 30/6735; H10D 62/121; H10D 84/851

(57) ABSTRACT

A semiconductor integrated circuit (IC) device includes a diffusion break region that has a diffusion break dielectric adjacent to or between diffusion break isolation wall(s). The diffusion break region may separate adjacent transistors. The diffusion break isolation wall(s) may include respective retained portions of a backside spacer, a bottom isolation, respective inner spacers, and residual active semiconductor nanolayers. The diffusion break region may be fabricated by depositing a diffusion break dielectric within a diffusion break opening against the diffusion break isolation wall(s).

### BACKGROUND

In modern semiconductor integrated circuit (IC) device fabrication, transistor devices that are formed within the semiconductor IC device are electrically isolated from one another to promote proper function in an electrical circuit. Typically, this is accomplished by forming a trench and filling the trench with an insulating material, such as silicon dioxide. Within the industry, these isolation regions may sometimes be referred to as diffusion breaks. In some applications, such as semiconductor IC devices employing gate all around (GAA) transistors, it may be difficult to form diffusion breaks as device sizes have decreased and packing densities have increased.

### SUMMARY

In an embodiment of the disclosure, a semiconductor integrated circuit (IC) device is presented. The semiconductor IC device includes an active region comprising a plurality of channels, a diffusion break region, a gate in direct contact with each of the plurality of channels and wrapped around the diffusion break region, and a frontside gate contact in direct contact with the gate and above and inset within the diffusion break region.

In an embodiment of the disclosure, a semiconductor integrated circuit (IC) device is presented. The semiconductor IC device includes an isolation region between an adjacent first transistor cell and second transistor cell. The first transistor cell includes a first plurality of channels. The second transistor cell includes a diffusion break region. The semiconductor IC device includes a first gate in direct contact with each of the first plurality of channels and wrapped around the diffusion break region. The semiconductor IC device includes a frontside gate contact in direct contact with the first gate and above and inset within the diffusion break region. The semiconductor IC device includes a transistor includes a second plurality of channels between a first source/drain (S/D) region and a second S/D region and a second gate in direct contact with each of the second plurality of channels.

In an embodiment of the disclosure, a semiconductor integrated circuit (IC) device fabrication method is presented. The method includes forming a diffusion break opening by removing a replacement gate and active semiconductor nanolayers from a backside of the semiconductor IC device. The well surface of the diffusion break opening is below an upper surface of the replacement gate. The method includes forming a diffusion break region by depositing a diffusion break dielectric within the diffusion break opening. The method further includes forming a frontside gate contact in direct contact with the replacement gate located above and inset within the diffusion break region.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1A and FIG. 1B depict respective cross-section views of a semiconductor IC device that includes a diffusion break region with gate access inline therewith, according to one or more embodiments of the disclosure.

FIG. 2 depicts a partial structure top-down view of an illustrative semiconductor IC device that includes a diffusion break region with gate access inline therewith, according to one or more embodiments of the disclosure.

FIG. 3 through FIG. 14 depict various fabrication structure cross-section views of an illustrative semiconductor IC device that includes a diffusion break region with gate access inline therewith, according to one or more embodiments of the disclosure.

FIG. 15 depicts a method of fabricating a semiconductor IC device that includes a diffusion break region that includes diffusion break region with gate access inline therewith, according to one or more embodiments of the disclosure.

### DETAILED DESCRIPTION

The embodiments of the present disclosure relate to fabrication methods and resulting structures for semiconductor devices. More specifically, the present disclosure relates to fabrication methods and resulting semiconductor integrated circuit (IC) devices that include a diffusion break region that includes a diffusion break dielectric adjacent to or between diffusion break isolation wall(s). The diffusion break region may separate adjacent transistors, such as GAA FETs. The diffusion break region may be fabricated by removing the substrate structure underneath the gate spacer, inner spacers, and replacement gate and between backside contact placeholders of the GAA FET. The diffusion break region may be further fabricated by forming one or more backside spacer(s) underneath the gate spacer and/or inner spacers. The diffusion break region may be further fabricated by forming a diffusion break opening by utilizing the backside spacer(s) as an etch mask and removing the bottom isolation (if present), the replacement gate, and the active semiconductor nanolayers from the backside of the semiconductor IC device. The diffusion break isolation wall(s) may include respective retained portions of the backside spacer(s), the bottom isolation (if present), the inner spacers, and the active semiconductor nanolayers. The diffusion break region may further be fabricated by depositing the diffusion break dielectric within the diffusion break opening against the diffusion break isolation wall(s).

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for improved channel electrostatics control.

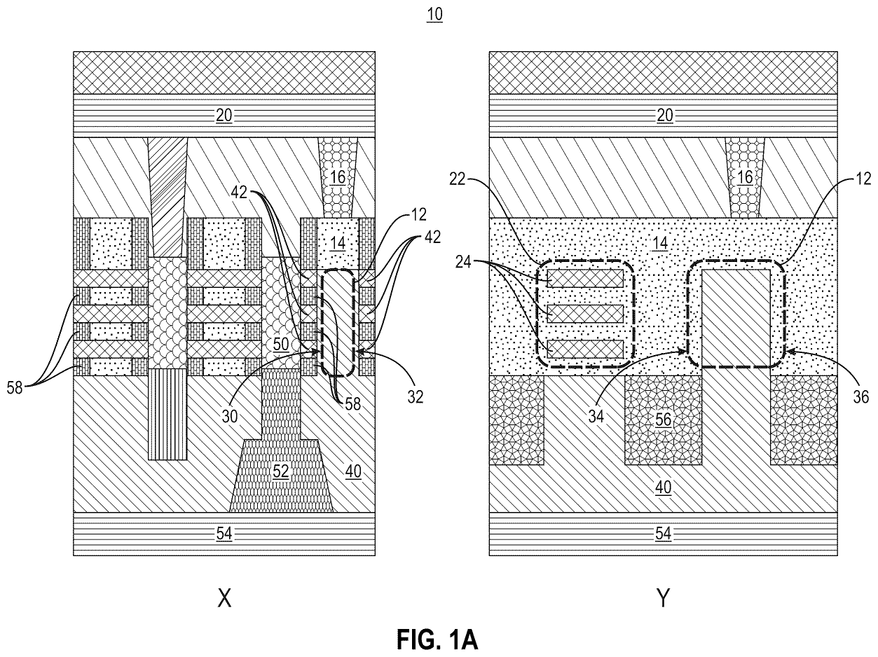

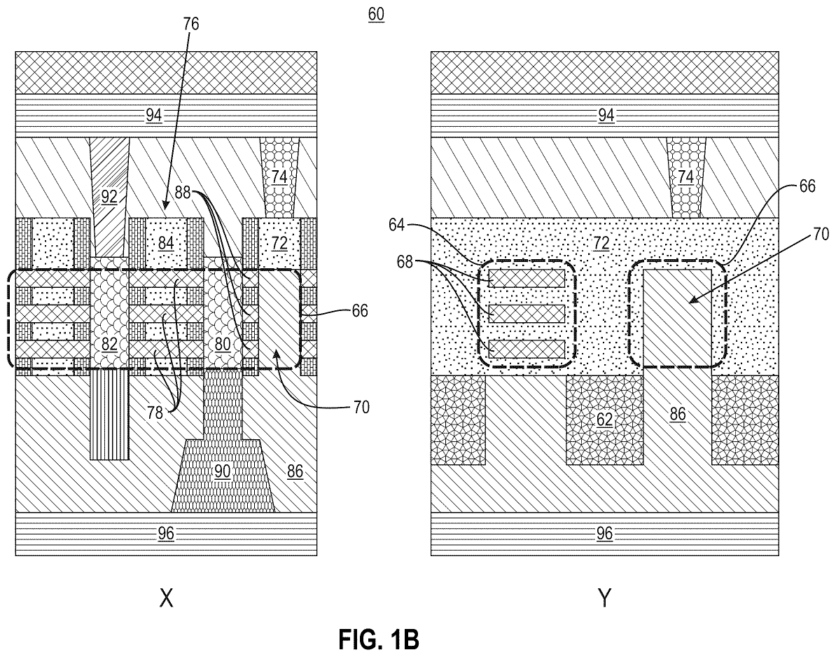

Referring now to the figures, FIG. 1A depicts a semiconductor IC device 10 that includes a diffusion break region 12 with gate 14 access inline therewith, according to one or more embodiments of the disclosure. For example, gate 14 is vertically inline and above the diffusion break region 12. In other words, diffusion break region 12 does not extend from the bottom of the gate 14 to the top of the gate 14. Rather, the top surface of the diffusion break region 12 is below the top surface of the gate 14. This effectively increases the top surface area of the gate 14 and allows for a gate contact 16 to land on or directly contact the gate 14 above the diffusion break region 12, which may ease signal routing congestion to or from the gate 14 and a frontside back end of line network 20.

In a particular embodiment of the disclosure, the semiconductor IC device 10 includes an active region 22 comprising a plurality of channels 24. The semiconductor IC device 10 includes the diffusion break region 12 and the gate 14 in direct contact with each of the plurality of channels 24 and wrapped around the diffusion break region 12. For example, as depicted in the Y cross-section, the gate 14 is wrapped around or in direct contact with a left, top, and right side of the diffusion break region 12. The semiconductor IC device 10 includes the frontside gate contact 16 in direct contact with the gate 14 and above and inset within a footprint of the diffusion break region 12. For example, the frontside gate contact 16 is inset within a footprint of the diffusion break region 12 that is formed by lateral boundaries 30, 32, 34, and 36 thereof.

In an example, the diffusion break region comprises or consists of a backside interlayer dielectric (ILD) 40. In an example, the backside ILD 40 is directly connected to a plurality of faux channels 42. In an example, charge carriers do not flow through the plurality of faux channels 42. For example, charge carriers do not flow through the plurality of faux channels 42 but otherwise would flow through the faux channels 42 if the gate 14 was in direct contact therewith.

In an example, a top surface of the backside ILD 40 is between a top surface of a topmost channel of the plurality of channels 24 and a top surface of the gate 14. Alternatively, in an example, a top surface of the backside ILD 40 is substantially coplanar with a top surface of a topmost channel of the plurality of channels 24.

In an example, the semiconductor IC device 10 includes a source/drain (S/D) region 50 in direct contact with the plurality of faux channels 42 and includes a backside contact 52 in direct contact with the S/D region 50 and in direct contact with the backside ILD 40.

In an example, the semiconductor IC device 10 includes the frontside back end of line (BEOL) network 20 directly connected to the frontside gate contact 16 and further includes a backside BEOL network 54 direct connected to the backside contact 52. In another example, the semiconductor IC device 10 includes a shallow trench isolation (STI) region 56 below the gate 14 and between the active region 22 and the diffusion break region 12.

In another example, the semiconductor IC device 10 includes a first inner spacer 58 between two faux channels of the plurality of faux channels 42 that is in direct contact with the backside ILD 40 and that is in direct contact with the S/D region 50.

FIG. 1B depicts a semiconductor IC device 60 that includes a diffusion break region with gate access inline therewith, according to one or more embodiments of the disclosure. The semiconductor IC device 60 includes an isolation region 62 between an adjacent first transistor cell 64 and second transistor cell 66. The first transistor cell 64 includes a first plurality of channels 68 and the second transistor cell includes a diffusion break region 70. The semiconductor IC device 60 further includes a first gate 72 in direct contact with each of the first plurality of channels 68 and wrapped around the diffusion break region 70. The semiconductor IC device 60 further includes a frontside gate contact 74 in direct contact with the first gate 72 and above and inset within the diffusion break region 70. The semiconductor IC device 60 further includes a transistor 76 that includes a second plurality of channels 78 between a first source/drain (S/D) region 80 and a second S/D region 82 and a second gate 84 in direct contact with each of the second plurality of channels 78.

In an example, the diffusion break region 70 comprises or consists of a backside interlayer dielectric (ILD) 86. In an example, the backside ILD 86 is directly connected to a plurality of faux channels 88. In an example, charge carriers do not flow through the plurality of faux channels 88.

In an example, a top surface of the backside ILD 86 is between a top surface of a topmost channel of the first plurality of channels 68 and a top surface of the first gate 72. In an example, a top surface of the backside ILD 86 is substantially coplanar with a top surface of a topmost channel of the first plurality of channels 68.

In an example, the semiconductor IC device 60 further includes a backside contact 90 in direct contact with the first S/D region 80 and in direct contact with the backside ILD 86 and further includes a frontside contact 92 in direct contact with the second S/D region 82. In an example, the semiconductor IC device 60 further includes a frontside back end of line (BEOL) network 94 directly connected to the frontside gate contact 74 and directly connected to the frontside contact 92 and further includes a backside BEOL network 96 direct connected to the backside contact 90. In an example, the plurality of faux channels 88 are each directly connected to the first S/D region 80.

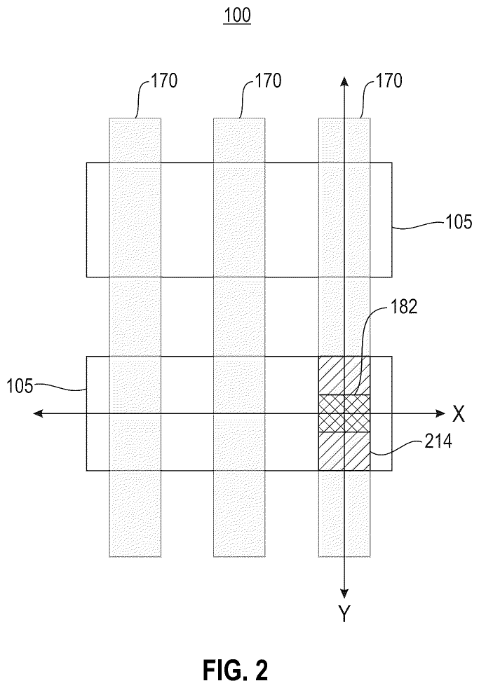

FIG. 2 depicts a partial structure top-down view of an illustrative semiconductor IC device 100 that includes a diffusion break region with gate access inline therewith, according to one or more embodiments of the disclosure. As currently depicted, semiconductor IC device 100 includes nanolayer rows 105, replacement gate structures 170, frontside gate contact 182 and diffusion break region 214. FIG. 2 also depicts cross-sectional planes of the various cross-sectional views of at least some of the drawings. The X cross-sectional plane is through a nanolayer row 105 and across replacement gate structures 170. The Y cross-sectional plane is through a replacement gate structure 170 and across nanolayer rows 105.

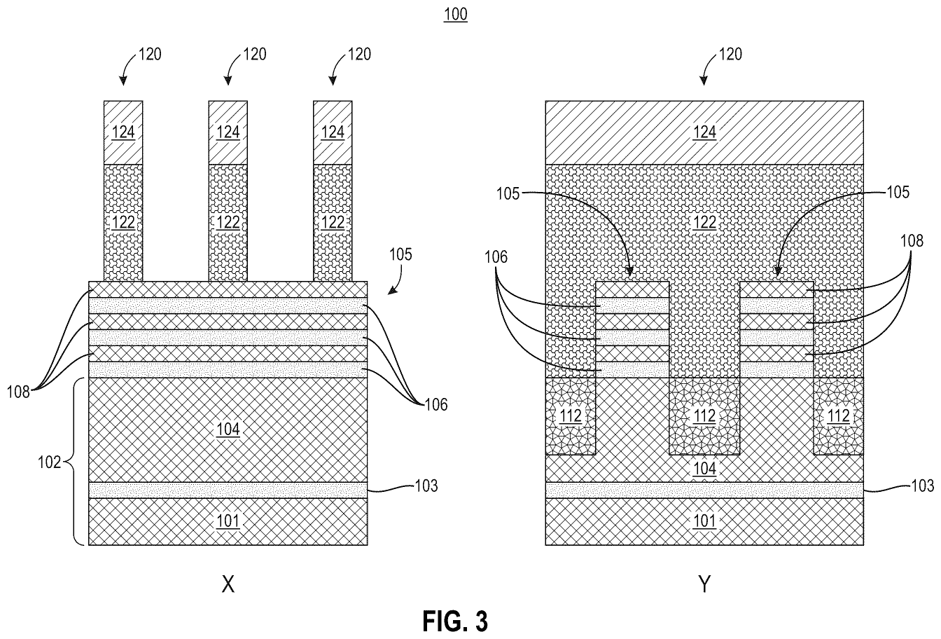

FIG. 3 depicts an initial fabrication structure cross-section view of the illustrative semiconductor IC device 100 that includes a diffusion break region with gate access inline therewith, according to one or more embodiments of the disclosure.

At this initial fabrication stage, the semiconductor IC device 100 may include a substrate structure 102. The substrate structure 102 may include a lower substrate 101, an etch stop layer 103, an upper substrate 104. The semiconductor IC device 100 may also include STI region(s) 112, nanolayer rows 105, and sacrificial gate structures 120.

For clarity, various background fabrication stages are described below that may be used to form the depicted semiconductor IC device 100. These background fabrication stages may reference structures that are not shown in the present cross-sections, but descriptions of the formation thereof are included herein to more fully enable the illustrated semiconductor IC device 100.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In the depicted implementation, the substrate structure includes an upper substrate 104, a lower substrate 101, and an etch stop layer 103 between the upper substrate 104 and the lower substrate 101. The upper substrate 104 and the lower substrate 101 may be comprised of any suitable material(s) including those listed above, and the etch stop layer 103 may be a dielectric material with etch selectivity to one or both of the upper substrate 104 and/or the lower substrate 101. In one example, the etch stop layer 103 may be an oxide and the substrate structure may be referred to as a buried oxide (BOX) substrate. In another example, the etch stop layer 103 may be a semiconductor (e.g., Silicon Germanium (SiGe)) and may be epitaxially grown from the top surface of lower substrate 101 and the upper substrate 104 may be epitaxially grown from the top surface of etch stop layer 103.

Next, the illustrative semiconductor IC device 100 may be formed by forming nanolayers over the substrate structure by forming a series of alternating sacrificial nanolayers 106 and active nanolayers 108, thereupon. In certain examples, the bottommost sacrificial nanolayer 106 is initially formed directly on an upper surface of the substrate structure 102. In other examples, certain layer(s) may be formed between the upper surface of the substrate structure 102 and the bottommost sacrificial nanolayer 106.

The sacrificial nanolayers 106 can have Ge percentages ranging from 20% to 45%. In an implementation, the alternating active sacrificial nanolayer and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

It should be appreciated that any suitable number of alternating nanolayers may be formed. Although it is specifically contemplated that the bottommost sacrificial nanolayer and the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers 106 and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

Further, in the depicted fabrication stages, the nanolayers may be patterned into nanolayer rows 105 and STI regions 112 may be formed within the substrate structure 102 adjacent to the nanolayer rows 105.

To form one or more nanolayer rows 105, a mask layer (not shown) may be formed on the uppermost nanolayer. The mask layer may be comprised of any suitable mask material(s). The mask layer may be patterned and used to perform the nanolayer row 105 patterning process. In the nanolayer row 105 patterning process, any suitable material removal process (e.g., reactive ion etching or RIE) may be used to remove portions of the alternating nanolayers down to the level of the substrate structure 102, or the like. Following the nanolayer row 105 patterning process, the one or more nanolayer rows 105 are formed. Subsequently, the mask layer may be removed.

The removal of undesired portion(s) of the nanolayers may further remove undesired portions of substrate structure 102 that are adjacent to respective footprints of nanolayer rows 105 to form STI region openings. The etch may be timed or otherwise controlled to stop the removal of the substrate structure 102 such that the depth or bottom of the one or more STI region openings has a predetermined or desired dimension. For example, the depth or bottom of the one or more STI region openings may be above the etch stop layer 103.

A STI region 112 may be formed upon and/or within the substrate structure 102 within respective STI region openings. The STI regions 112 may be formed by depositing electrical dielectric material(s) within respective STI region opening(s) that are adjacent to the one or more nanolayer rows 105. A top surface of the one or more STI regions 112 may be initially coplanar with or below a top surface of the substrate structure 102. In some implementations, further fabrication operations may generally remove portions of the STI regions 112 (e.g., sacrificial gate removal, replacement gate fabrication pre-clean, etc.), such that the top surfaces of the STI regions 112 are below the top surface of the substrate structure 102.

The one or more STI regions 112 may have a volume and/or geometry that sufficiently electrically isolates components or features of neighboring transistors and/or may sufficiently electrically isolate neighboring nanolayer rows 105.

In an example, the STI region(s) 112 may be formed by depositing a STI liner within the STI region openings. Subsequently, STI region(s) 112 may be further formed by depositing STI dielectric material upon the STI liner. A etch back, recess, or the like, may occur to remove undesired or over formed STI liner and/or STI dielectric material, such that the top surface of the STI region(s) are coplanar with or below a bottom surface of the bottommost sacrificial nanolayer. STI liner may be composed of but not limited to a nitride, low-K nitride (i.e., a nitride material with a lower dielectric constant relative to SiO₂), or the like. The STI dielectric material may be composed of but not limited to an oxide, low-K oxide (i.e., an oxide material with a lower dielectric constant relative to SiO₂), or the like. For clarity, as the STI regions 112 are formed within the substrate structure 120 and may form substrate tracks between the STI regions 112. Upon the substrate tracks numerous transistors may be formed.

The illustrated semiconductor IC device 100 may be further fabricated by next forming sacrificial gate structures 120. The sacrificial gate structures 120 may include a sacrificial gate liner (not shown), a sacrificial gate 122, and a sacrificial gate cap 124. The sacrificial gate structures 120 may be formed by initially depositing a sacrificial gate liner layer (e.g., a dielectric, oxide, or the like) upon the one or more STI regions 112 and upon and around the one or more nanolayer rows 105. The sacrificial gate structures 120 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 105. The sacrificial gate structures 120 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 120 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 122, and the sacrificial gate cap 124, respectively, of each of the one or more sacrificial gate structures 120.

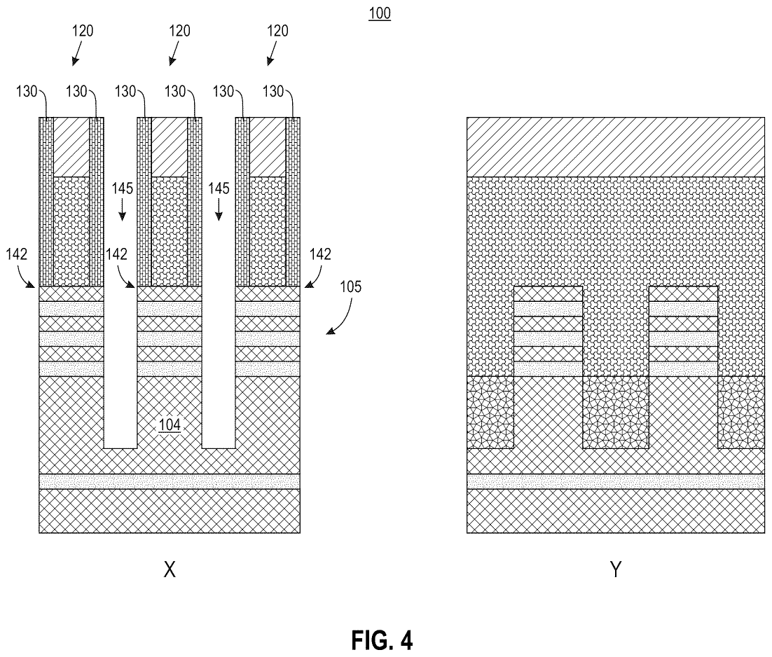

FIG. 4 depicts an fabrication structure cross-section view of the illustrative semiconductor IC device 100 that includes a diffusion break region with gate access inline therewith, according to one or more embodiments of the disclosure. At the present fabrication stage, gate spacers 130 and S/D region canyons 145 may be formed.

The gate spacer(s) 130 may be formed upon the sidewall(s) of the sacrificial gate structures 120, upon the STI region(s) 112, and around the one or more nanolayer rows 105. The gate spacer(s) 130 may be formed by a conformal deposition of a dielectric material, such as silicon nitride, SiBCN, SiNC, SiN, SiCO, SiNOC, or a combination thereof, or the like upon STI regions 112, upon around the one or more sacrificial gate structures 120, and upon and around the one or more nanolayer rows 105. Subsequently, undesired portions of dielectric material may be removed while desired portions the dielectric material may be retained and thereby form the gate spacer(s) 130. The undesired portions of dielectric material may be removed by a directional ion etch, such as a reactive ion etch (RIE). The RIE may remove exposed or unprotected horizontal portions of the dielectric material while retaining the vertical portions of the dielectric layer (e.g., the gate spacer(s) 130).

The illustrated semiconductor IC device 100 may be further fabricated by next forming S/D region canyons 145 within the one or more nanolayer rows 105 between gate spacer(s) 130 of neighboring sacrificial gate structures 120. In other words, a single nanolayer row 105 may be separated, by one or more recesses, into multiple nanolayer stacks 142 with a respective nanolayer stack 142 being located underneath at a portion of respective sacrificial gate structure and associated gate spacer(s) 130.

The S/D region canyons 145 may be formed between adjacent sacrificial gate structures 120 by removing respective portions of the sacrificial nanolayers 106 and active nanolayers 108 that are between gate spacer(s) 130 of adjacent or neighboring sacrificial gate structures 120. The one or more S/D region canyons 145 may be formed to a depth to stop at the top surface of the substrate structure 102 (e.g., the top surface of upper substrate 104, or the like), the top surface of STI regions 112, or the like. Alternatively, the S/D region canyons 145 may be formed to a depth within the upper substrate 104 above the etch stop layer 103, as depicted.

The undesired portions of sacrificial nanolayers 106 and active nanolayers 108 may be removed by etching or other subtractive removal techniques. The top surface of the substrate structure 102 may be used as an etch stop or other etch parameters may be controlled to stop the material removal at or within the substrate structure 102. As the gate spacer(s) 130 and the sacrificial gate structures 120 may be utilized to protect the underlying portions of sacrificial nanolayers 106, active nanolayers 108, respective sidewalls of the nanolayer stacks 142 may be substantially coplanar and substantially vertical with the outer sidewalls of the gate spacer(s) 130 there above.

As used herein, “substantially vertical” sidewalls deviate from a direction normal to a major surface (e.g., top surface, etc.) of the substrate 102 by less than 5°, e.g., 0°, 1°, 2°, 3°, 4°, or 5°, including ranges between any of the foregoing values.

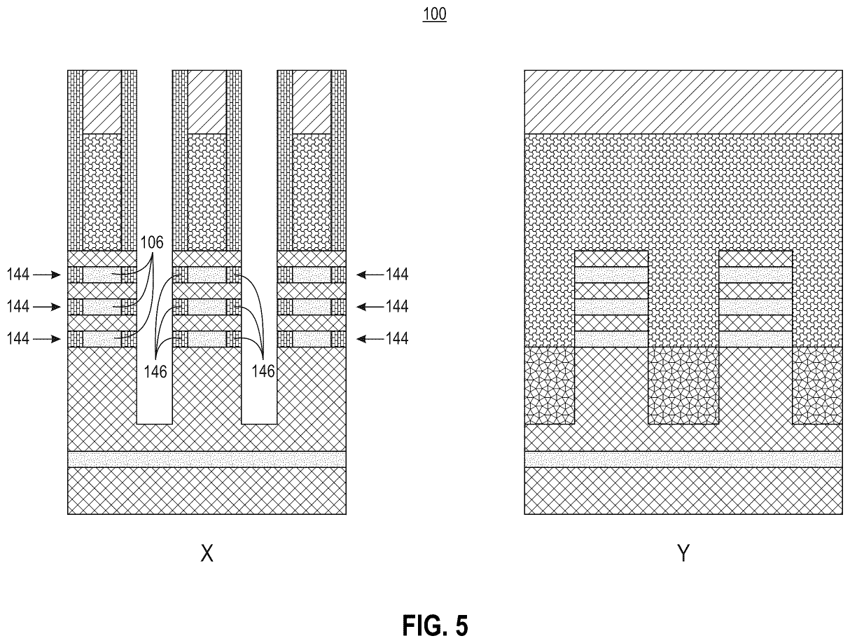

FIG. 5 depicts an fabrication structure cross-section view of the illustrative semiconductor IC device 100 that includes a diffusion break region with gate access inline therewith, according to one or more embodiments of the disclosure. At the present fabrication stage, inner spacers 146 may be formed.

The inner spacers 146 may be formed by forming horizontal or lateral indents 144 by laterally or horizontally removing respective portions of sacrificial nanolayers 106 within the nanolayer stacks 142. The indents 144 may be formed by a reactive ion etch (RIE) process, which can remove portions of the sacrificial nanolayers 106. The horizontal depth of the indents 144 may be chosen to set a length for a replacement gate structure that is formed in place of one sacrificial gate structure. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers 106 generally below spacer 130) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacer(s) 130, STI regions 112, and/or substrate structure 102.

The illustrated semiconductor IC device 100 may be further fabricated by next forming a respective inner spacer 146 within each indent. The one or more inner spacers 146 can be formed by ALD or CVD or any other suitable deposition technique that deposits a dielectric material within the indent(s) 144, thereby forming the inner spacer(s) 146. In some examples, the inner spacers 146 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacers 146 a directional etch process is performed to create substantially vertical sidewalls of the inner spacers 146 that are coplanar with the substantially vertical sidewalls of the active nanolayers 108, of the gate spacer(s) 130.

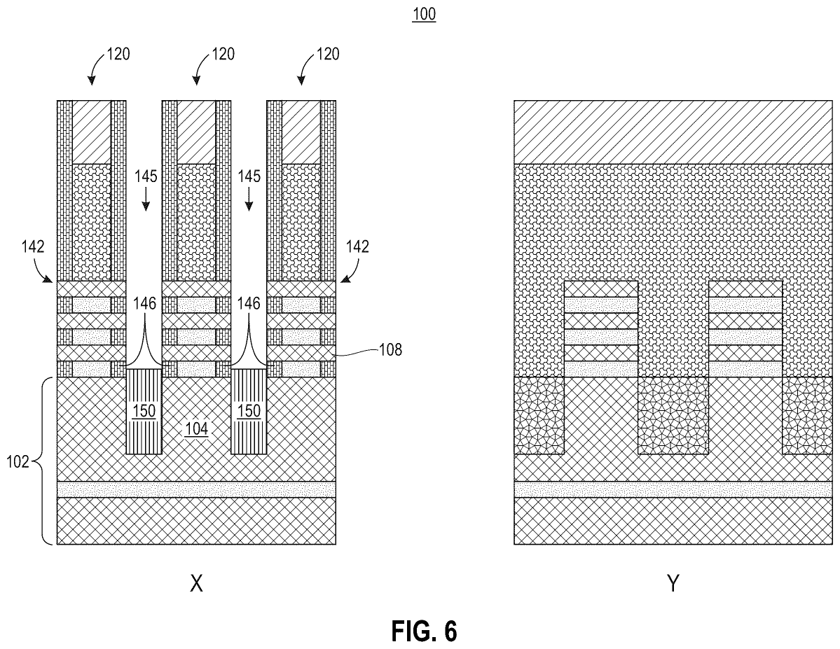

FIG. 6 depicts an fabrication structure cross-section view of the illustrative semiconductor IC device 100 that includes a diffusion break region with gate access inline therewith, according to one or more embodiments of the disclosure. At the present fabrication stage, backside contact placeholders 150 may be formed.

The backside contact placeholders 150 may be formed within the substrate structure 102 (e.g., within the upper substrate 104) in between adjacent sacrificial gate structures 120 within a respective S/D region canyon 145. In one example, a respective backside contact placeholder 150 may be formed in all recess location(s) such that a respective backside contact placeholder 150 is located underneath each S/D region within the semiconductor IC device 100.

If the S/D region canyon 145 are not of sufficient depth, the one or more backside contact placeholders 150 may be formed by increasing the depth of the S/D region canyon 145. The one or more backside contact placeholders 150 may be further formed by epitaxially growing an epitaxial material from exposed substrate structure 102 surface(s) within the S/D region canyon 145. In some embodiments, epitaxial growth and/or deposition processes may be selective to forming on the semiconductor surfaces of the upper substrate 104. In some embodiments a liner may be formed that may protect the surfaces of the semiconductor IC device 100 but for the substrate structure 102 surfaces of the S/D region canyon 145. As such, the epitaxial growth and/or deposition processes may occur from these exposed substrate structure 102 surfaces within the S/D region canyons 145.

In some embodiments, the epitaxial growth of the one or more backside contact placeholders 150 may overgrow above the top surface of the substrate structure 102. In an example, the epitaxial material of the one or more backside contact placeholders 150 may be chosen to be etch selective to the material of the S/D region(s), the material of the upper substrate 104, or the like. In an example, the top surface of the backside contact placeholders 150 are below a bottom surface of the bottom most active nanolayer 108 within the nanolayer stacks 142.

In an example, as depicted, a placeholder protective cap (not shown) may be formed within the S/D region canyon 145 upon the respective backside contact placeholder 150. The placeholder protective cap may be utilized to help protect or mask the associated backside contact placeholder 150 during the etching process(es) utilized to create a backside diffusion break opening. The placeholder protective cap(s) may be epitaxially grown. For example, the one or more backside contact placeholders 150 may be SiGe and the placeholder protective cap(s) may be Si. In these examples, the placeholder protective cap may be epitaxially grown from the associated backside contact placeholder 150.

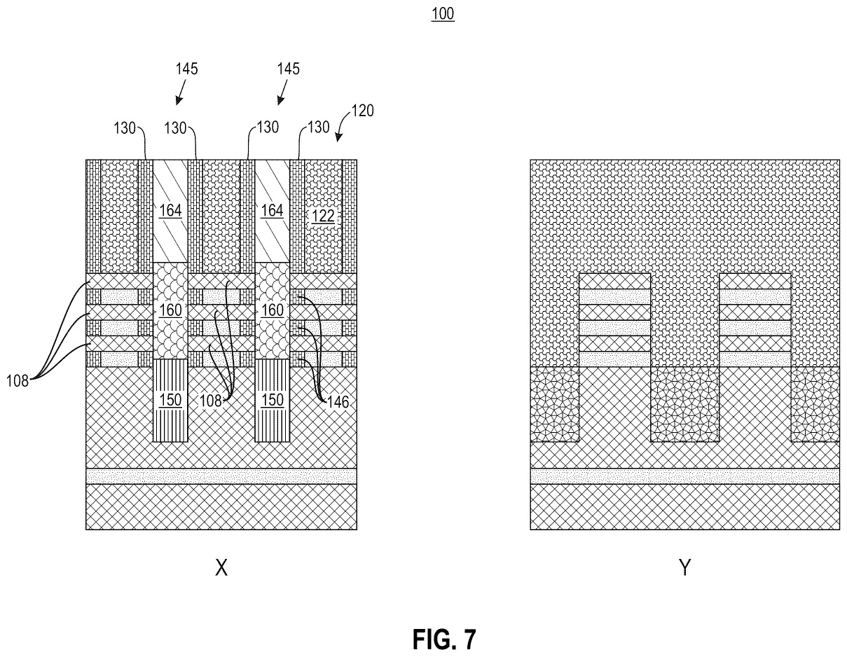

FIG. 7 depicts an fabrication structure cross-section view of the illustrative semiconductor IC device 100 that includes a diffusion break region with gate access inline therewith, according to one or more embodiments of the disclosure. At the present fabrication stage, S/D regions 160 and frontside ILD 164 may be formed.

The S/D regions 160 may be formed within a respective S/D region canyon 145 and upon or over a respective backside contact placeholder 150. For example, p-doped S/D regions 160 may be formed in a first formation sequence and then n-doped S/D regions 160 may be formed in a second formation sequence, or vice versa.

Each S/D region 160 may form either a source or a drain, respectively, of a respective transistor and is connected to respective end surfaces of the active nanolayers 108 of one or more nanolayer stacks 142. Each S/D region 160 may be composed of a semiconductor material and a dopant. Alternatively, S/D regions may be another applicable material, such as a metalloid, or the like. As used herein, a “source/drain” region can be a source region or a drain region depending on subsequent wiring and application of voltages during operation of the applicable transistor.

The semiconductor material that provides each of the S/D regions 160 may be composed of one of the semiconductor materials mentioned above for the semiconductor structure. For example, the semiconductor material that provides the S/D region 160 can be compositionally the same, or compositionally different from each active nanolayer 108. The dopant that may be present in the S/D regions 160 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type”refers to the addition of impurities that contributes free electrons to an intrinsic semiconductor. In a silicon containing semiconductor material, examples of n-type dopants, include, but are not limited to, antimony, arsenic and phosphorous. When the semiconductor material is doped with a p-type dopant, the resulting S/D regions 160 are referred to herein as being p-doped and when the semiconductor material is doped with a n-type dopant, the resulting S/D regions 160 are referred to herein as being n-doped.

The S/D regions 160 may be epitaxially grown or formed. In some examples, the S/D regions 160 are formed by in-situ doped epitaxial growth. The use of an in-situ doping process is merely an example. For instance, one may instead employ an ex-situ process to introduce dopants into the S/D regions 160. Other doping techniques can be used to incorporate dopants in the S/D regions 160. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, S/D epitaxial growth conditions promote in-situ Boron doped SiGe for p-type transistor and phosphorus or arsenic doped silicon or Si:C for n-type transistors.

In some examples, the epitaxial growth that forms the S/D region 160 occurs or is promoted from the top surface of the backside contact placeholders 150, the exposed sidewalls of the active nanolayers 108, or the like, while epitaxial growth may be limited or does not occur from neighboring STI regions 112.

In some embodiments, epitaxial growth to form the one or more S/D regions 160 may overgrow above the upper surface of the sacrificial gate structure(s) 120 and be subsequently recessed such that the top surface of the S/D region 160 may be substantially horizontal and above the top surface of the topmost active nanolayer 108 within the nanolayer stacks 142 (e.g., to enable contact between the end surface of that active nanolayer 108 and the S/D region 160).

The illustrated semiconductor IC device 100 may be further fabricated by next forming interlayer dielectric (ILD) 164. For example, a blanket ILD 164 may be deposited over the S/D region(s) 160, over the STI region(s) 112, over the sacrificial gate structures 120, and over the gate spacer(s) 130, and the like.

The ILD 164 can be any suitable material, such as, for example, porous silicates, carbon doped oxides, silicon dioxides, silicon nitrides, silicon oxynitrides, or other dielectric materials. Any known manner of forming the ILD 164 can be utilized. The ILD 164 can be formed using, for example, CVD, PECVD, ALD, flowable CVD, spin-on dielectrics, or PVD.

In an example, the ILD 164 may be formed to a thickness above the top surface of the sacrificial gate structures 120. Subsequently, a planarization process, such as a CMP, may be performed to remove excess ILD 164 material and to remove the sacrificial gate caps 124 of the sacrificial gate structures 120, thereby exposing the sacrificial gate 122 thereunder. The planarization may also partially remove some of the sacrificial gates 122 or may at least expose the sacrificial gate 122 of the sacrificial gate structures 120. The CMP may create a substantially planar or substantially horizontal top surface for the semiconductor IC device 100. In other words, the respective top surfaces of ILD 164, gate spacer(s) 130, sacrificial gates 122, S/D regions 160, etc. may be substantially coplanar and/or substantially horizontal.

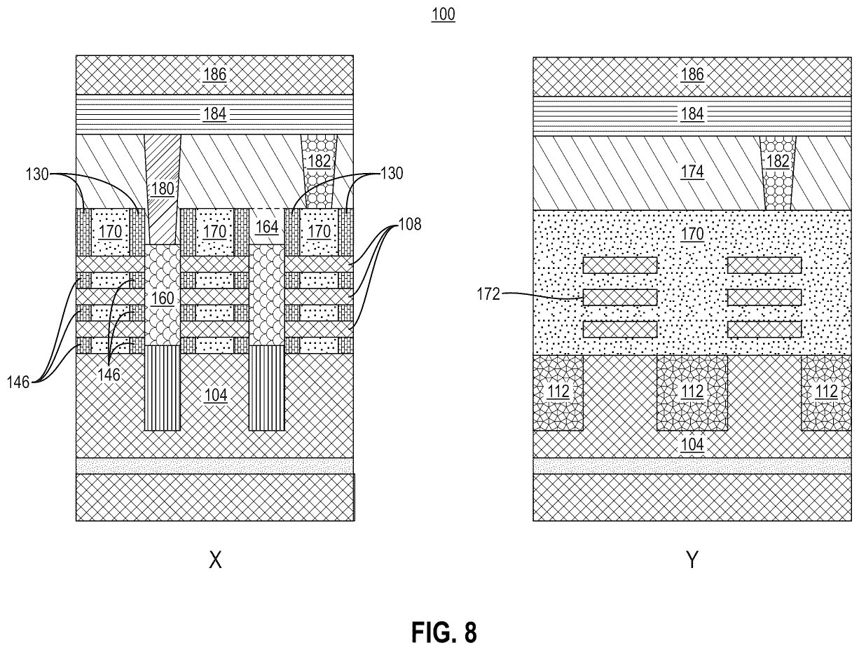

FIG. 8 depicts an fabrication structure cross-section view of the illustrative semiconductor IC device 100 that includes a diffusion break region with gate access inline therewith, according to one or more embodiments of the disclosure. At the present fabrication stage, replacement gate structures 170 may be formed, frontside contacts, such as frontside S/D contact 180 and frontside gate contact 182 may be formed, and a frontside back end of line (BEOL) network 184 may be formed.

Replacement gate structures 170 may be formed by removing the sacrificial gate structures 120 and then forming replacement gate structures 170 in place thereof. The sacrificial gate structures 120 may be removed by initially removing the sacrificial gate and sacrificial gate oxide by a removal technique, such as one or more series of etches. For example, such removal may be accomplished by a wet chemical etching process in which one or more chemical etchants are used to remove the sacrificial gate and sacrificial gate oxide of the sacrificial gate structures 120. Appropriate etchants may be used that remove the sacrificial gate and/or sacrificial gate oxide selective to the active nanolayers 108, inner spacers 146, gate spacer(s) 130, upper substrate 103, STI regions 112, or the like.

Next, or simultaneously, the active nanolayers 108 may be released by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 146, upper substrate 104, gate spacer(s) 130, or the like. After the removal of sacrificial nanolayers 106, void spaces may be formed above and/or below the active nanolayers 108.

The illustrated semiconductor IC device 100 may be further fabricated by forming a replacement gate structure 170 in place of the removed sacrificial gate structures 120 around the active nanolayers 108, upon STI region(s) 112, upon the upper substrate 104, etc.

Replacement gate structure(s) 170 may be formed by initially forming an interfacial layer on the gate spacer(s) 130, on the active nanolayers 108, upon STI region(s) 112, upon the upper substrate 104, on the inner spacers 146, etc. that are interior to and/or upon the respective surfaces interior to the opening created by the removal of the sacrificial gate structure and the releasing of the active nanolayers 108. The interfacial layer can be deposited by any suitable techniques, such as ALD, CVD, PVD, thermal oxidation, combinations thereof, or other suitable techniques.

The replacement gate structure(s) 170 may be further formed by forming a high-k layer to cover the exposed surfaces of the interfacial layer. The high-K layer can be deposited by any suitable techniques, such as ALD, CVD, metal-organic CVD (MOCVD), PVD, thermal oxidation, combinations thereof, or other suitable techniques. A high-K material is a material with a higher dielectric constant than that of SiO₂, and can include e.g., LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃(BST), Al₂O₃, Si₃N₄, oxynitrides (SiON), or other suitable materials. The high-K layer can include a single layer or multiple layers, such as metal layer, liner layer, wetting layer, and adhesion layer. In other embodiments, the high-K layer can include, e.g., Ti, Ag, Al, TiAlN, TaC, TaCN, TaSiN, Mn, Zr, TiN, TaN, Ru, Mo, Al, WN, Cu, W, or any suitable materials.

The replacement gate structure(s) 170 may be further formed by depositing a work function (WF) gate upon the high-κ layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-κ layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the nanolayer channel.

The replacement gate structure(s) 170 may be further formed by depositing a conductive gate 172. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layer, the high-κ layer, the WF gate, or the like, are utilized in the replacement gate structures, the conductive gate may be formed upon the most recent structural formation thereof.

The conductive gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. The conductor material and/or metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 164, gate spacer(s) 130, replacement gate structures 170, or the like, may be substantially horizontal and/or may be substantially coplanar.

The illustrated semiconductor IC device 100 may be further fabricated by next forming a frontside contact ILD 174. The frontside contact ILD 174 may be formed upon respective top surfaces of replacement gate structure(s) 170, ILD 164, and gate spacer(s) 130. The frontside contact ILD 174 may be formed by depositing a dielectric material, such as, for example, porous silicates, carbon doped oxides, silicon dioxides, silicon nitrides, silicon oxynitrides, or other dielectric materials. Any appropriate deposition technique for forming the frontside contact ILD 174 can be utilized. The frontside contact ILD 174 can be formed using, for example, CVD, PECVD, ALD, flowable CVD, spin-on dielectrics, or PVD.

The illustrated semiconductor IC device 100 may be further fabricated by next forming frontside contacts within the frontside contact ILD 174 and the ILD 164. The frontside contacts may be frontside S/D contacts 180, which may respectively contact a particular S/D region 160 and/or may be frontside gate contacts 182, which may respectively contact a particular replacement gate structure 170.

The frontside contacts may be in direct or indirect physical and electrical contact and/or with respective material(s) of one or more regions of the semiconductor IC device 100. For example, an illustrated frontside S/D contact 180 is in direct contact with S/D region 160. A different frontside gate contact 182 may be in direct contact with a particular replacement gate structure 170.

The frontside contacts may be formed by initially forming frontside contact opening(s). The frontside contact opening(s) may be formed by the same or shared lithography and etch process(es) or by sequential lithography and etch processes. In such process(es), a mask may be applied and patterned. An opening in the patterned mask may expose the portion of the underlying contact ILD 174 and/or ILD 164 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention. Generally, the frontside contact openings expose at least a portion of the underlying semiconductor IC device 100 structure that which the associated frontside contact 180 is to make direct contact therewith.

The frontside contact(s) may be further formed by depositing conductive material such as metal into the respective frontside contact opening(s). In an example, frontside contact(s) 180 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. Subsequently, the respective top surfaces of frontside contact(s) 180 and the frontside contact ILD 174 may be substantially horizontal and/or substantially coplanar. In embodiments, the frontside contact(s) are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and the BEOL that includes material to prevent the diffusion of BEOL metals to FEOL devices.

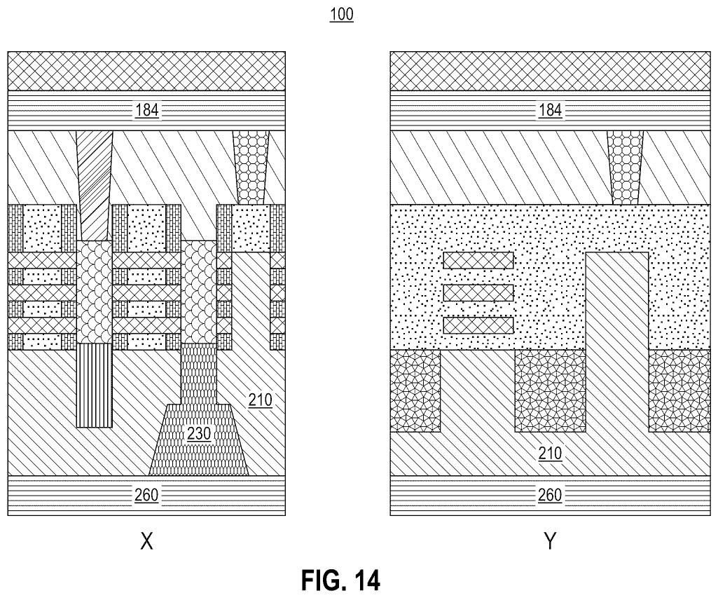

The BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 184 is formed on the frontside of the semiconductor device 100. Subsequently, a backside BEOL network 260, as depicted in FIG. 14, is formed.

In the depicted example, the frontside BEOL network 184 is formed over the contact ILD 174 and upon the frontside contacts. Respective wires within the frontside BEOL network 184 may be electrically connected to the one or more S/D regions 160, to the one or more replacement gate structure(s) 170, or the like, by a respective frontside contact(s). For example, respective wire(s) within the frontside BEOL network 184 may be electrically connected to appropriate S/D regions 160 by a frontside S/D contact 180, another and different group of respective wire(s) within the frontside BEOL network 184 may be electrically connected to appropriate replacement gate structures 170 by a frontside gate contact 182, etc.

In different implementations, the frontside contacts may take the form of BEOL interconnects. In these implementations, the respective wires within the frontside BEOL network 184 may be electrically connected to the S/D regions 160, replacement gate structure(s) 170, or the like, by a lowest BEOL interconnect, such as a vertical interconnect access (VIA), that is within the frontside BEOL network 184.

The frontside BEOL network 184 is located directly on the frontside surface of the MOL structure (e.g., contact ILD 174, frontside contact(s) 180, etc.). The frontside BEOL network 184 can include one or more interconnect dielectric material layers (including one of the dielectric materials mentioned above for the frontside ILD 164) and contains metal wires (the metal wires can be composed of any electrically conductive metal or electrically conductive metal alloy) embedded therein. In some embodiments, the frontside metal wires within the frontside BEOL network 184 are composed of Cu. The frontside BEOL network 184 can include “x” numbers of frontside metal levels, wherein “x” is an integer starting from 1. The frontside BEOL network 184 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by bonding carrier wafer 186 to the frontside BEOL network 184. The carrier wafer 186 can include one of the semiconductor materials mentioned above for the semiconductor structure and the carrier wafer 186 may be attached to the semiconductor IC device 100 by a wafer-to-wafer bonding technique.

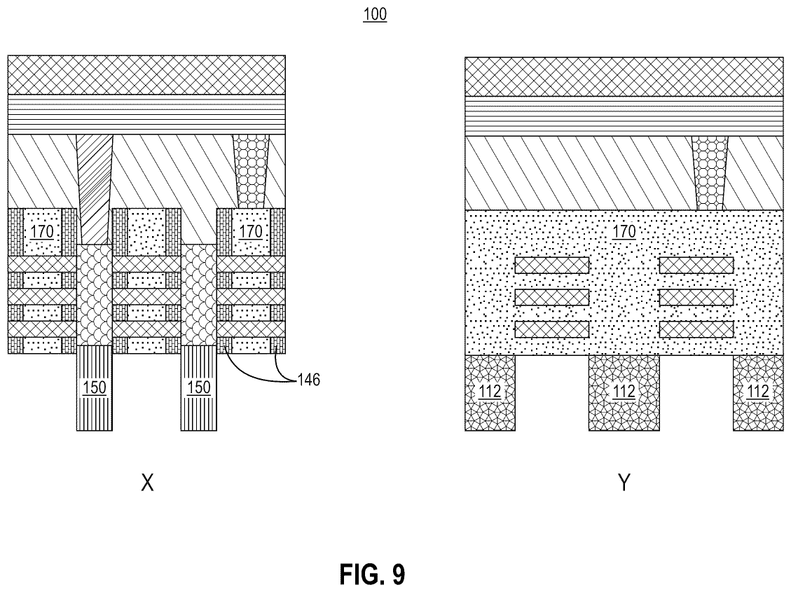

FIG. 9 depicts an fabrication structure cross-section view of the illustrative semiconductor IC device 100 that includes a diffusion break region with gate access inline therewith, according to one or more embodiments of the disclosure. At the present fabrication stage, the substrate structure may be recessed. For example, the lower substrate 101 the etch stop layer 103, and the upper substrate 104 may be removed.

The substrate structure may be recessed by flipping the semiconductor IC device 100 and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

The etch stop layer 103 may be removed by a subtractive removal technique such as a CMP, dry and/or wet etch. Upon removal of the etch stop layer 103, the bottom surface upper substrate 104 is exposed. The removal of etch stop layer 103 may be selective to the material of upper substrate 104. For example, etch stop layer 103 is removed by an etch that utilizes upper substrate 104 as the etch stop.

The upper substrate 104 may be removed by an appropriate substrative removal technique, such as an etch. The etch may be timed or otherwise controlled to remove the material of the upper substrate 104 selective to the STI regions 112, to the backside contact placeholders 150, to the replacement gate structures 170, to the inner spacers 146, or the like. The remove upper substrate 104 may expose the backside surface(s) of the bottommost inner spacers 146, replacement gate structures 170, and may at least partially expose the backside contact placeholders 150.

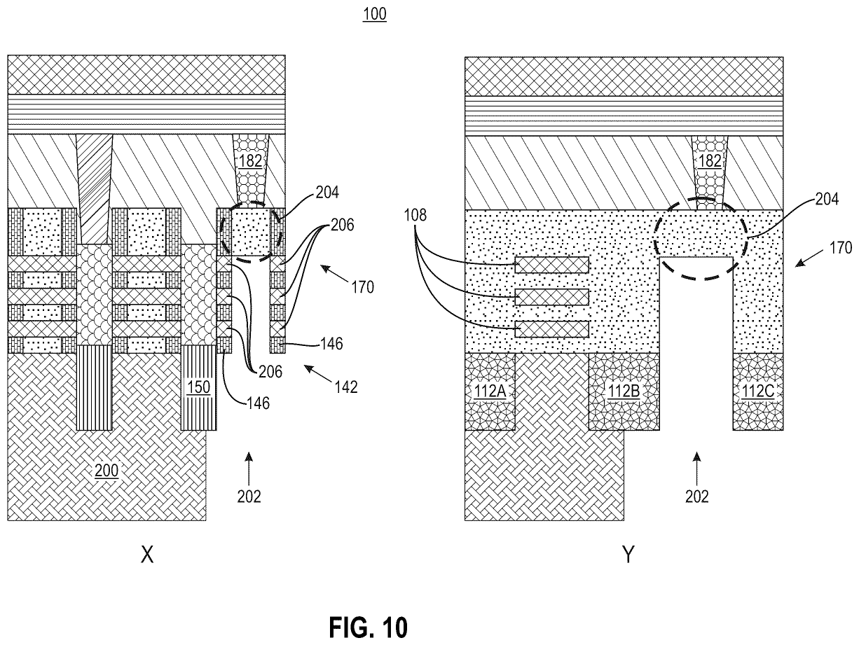

FIG. 10 depicts an fabrication structure cross-section view of the illustrative semiconductor IC device 100 that includes a diffusion break region with gate access inline therewith, according to one or more embodiments of the disclosure. At the present fabrication stage, a diffusion break opening 202 may be formed.

The diffusion break opening 202 may be formed by lithography and etch process(es). In such process(es), a mask 200 may be applied and patterned. An opening in the patterned mask may expose an associated replacement gate structure 170 and nanolayer stack 142 between STI regions 112 and between neighboring backside contact placeholders 150 to be partially removed while other protected portions of semiconductor IC device 100 thereunder may be protected and retained. Generally, the etching processes may remove the portion of the replacement gate structure 170 and the active nanolayers 108 within the nanolayer stack 142 that are between associated inner spacers 146 and between neighboring STI regions 112. In such process(es), the etching processes can have etching parameters that can be tuned, such as etchants used, etching temperature, etching solution concentration, etching pressure, source power, RF bias voltage, RF bias power, etchant flow rate, to promote desired material removal and retention of at least a portion 204 of the replacement gate structure 170 that is directly below the frontside gate contact 182. In an example, the bottom surface of the portion 204 of the replacement gate structure 170 is above a top surface of the topmost active nanolayers 108. For clarity, the frontside gate contact 182 that is connected to the replacement gate structure 170 may be located above relatively different transistor cell located between STI region 112B and STI region 112C than a reference cell between STI region 112A and STI region 112B, as depicted in The Y cross-section. As such, depending upon specific implementations, wire congestion from the replacement gate structure 170 to the frontside BEOL network 186 may be eased or reduced.

In certain implementations, a directional etch process may performed to create substantially vertical sidewalls of the diffusion break isolation walls formed by the residual inner spacers 146 and residual active nanolayers 108, which may be hereinafter referred to as faux channel portions 206. In alternative implementations, the etch may result in angled sidewalls such that a horizontal perimeter dimension near the bottom of the diffusion break opening 202 that is larger than a horizontal perimeter dimension near the top of the backside diffusion break opening 202. These angled sidewalls may be the result of the backside etch direction of the backside diffusion break opening 202.

For clarity, each diffusion break isolation wall may include alternating inner spacers 146 and faux channel portions 206. The term faux channel portion is defined herein to mean a region formed of the same material as the active nanolayers 108 but that which current does not pass through as does current passing through the active nanolayers 108. Subsequently, mask 200 may be removed by a substrative removal technique, such as an etch, ash, or the like.

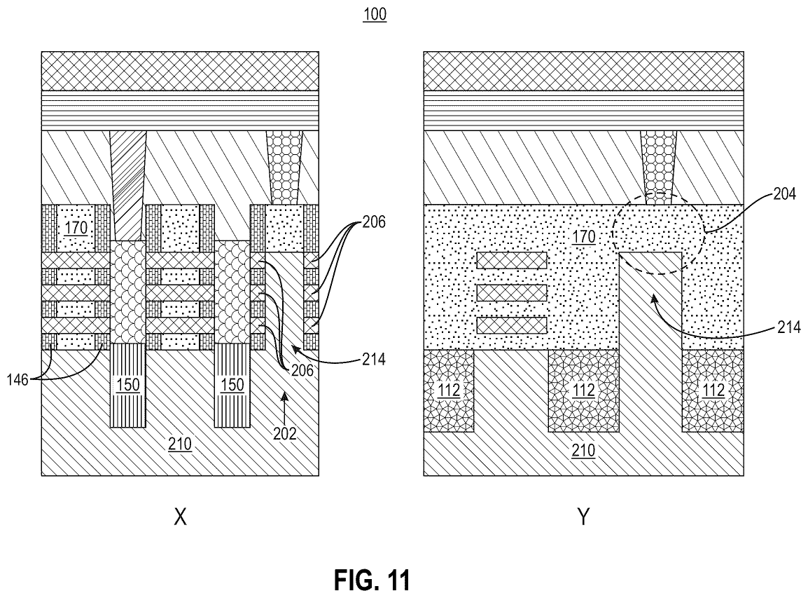

FIG. 11 depicts an fabrication structure cross-section view of the illustrative semiconductor IC device 100 that includes a diffusion break region with gate access inline therewith, according to one or more embodiments of the disclosure. At the present fabrication stage, backside ILD 210 may be formed upon the exposed backside of the semiconductor IC device 100.

The backside ILD 210 may be formed within the backside diffusion break opening 202, and upon respective sidewall(s) of the diffusion break isolation wall(s), thereby forming the diffusion break region 214, and may also be formed upon the backside contact placeholders 150, upon the backside surfaces of the replacement gate structures 170, and the bottommost inners spacers 146. For example, the backside ILD 210 may be formed against respective sidewalls of the alternating inner spacers 146 and faux channel portions 206 within the diffusion break opening 202. The backside ILD 210 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 210 can be utilized. The backside ILD 210 can be formed using, for example, CVD, PECVD, ALD, flowable CVD, spin-on dielectrics, or PVD.

In an example, the material of the backside ILD 210 may be the same material or relatively different material as the frontside ILD 164 and/or the frontside contact ILD 174. For example, frontside ILD 174 may be silicon dioxide and the backside ILD 210 may be a low-κ dielectric material. For clarity, the backside ILD 210 that remains within the backside diffusion break opening 202 may form the diffusion break region 214.

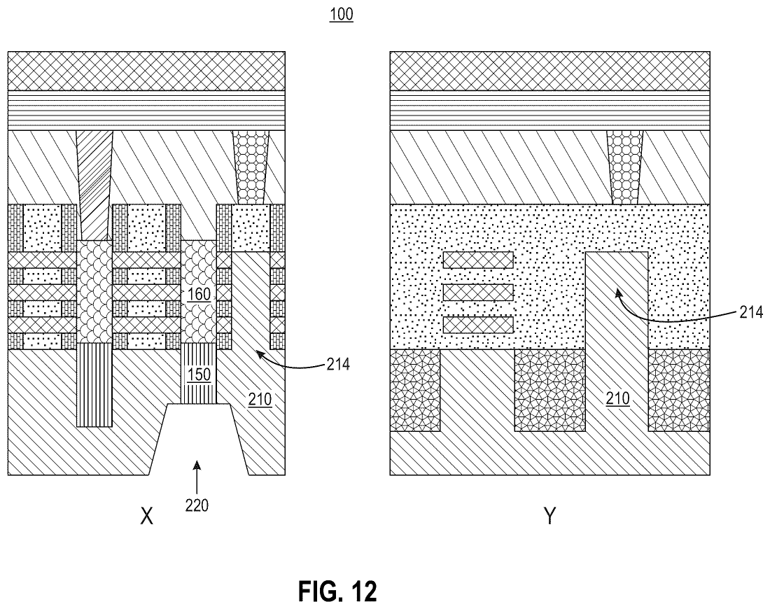

FIG. 12 depicts an fabrication structure cross-section view of the illustrative semiconductor IC device 100 that includes a diffusion break region with gate access inline therewith, according to one or more embodiments of the disclosure. At the present fabrication stage, respective backside contact placeholders 150 may be exposed and backside contact openings 220 may be formed.

The respective backside contact placeholders 150 may be formed by the same or shared lithography and etch process(es), or sequential lithography and etch processes. In such process(es), a mask may be applied to the backside of the semiconductor IC device 100 and patterned. Openings in the patterned mask may be used to remove the backside ILD 210 and at least expose or partially remove the backside contact placeholder(s) 150 that are inline with the mask openings, while other protected portions of semiconductor IC device 100 may be protected and retained. The patterning of backside ILD 210 and exposing of the associated backside contact placeholder(s) 150 may partially form respective backside contact openings 220.

The backside contact openings 220 may be fully formed by removing the associated and exposed backside contact placeholders 150. The backside contact placeholders 150 that are exposed by respective backside contact opening(s) 220 may be removed by a substrative removal technique, such as an etch. The removal of the backside contact placeholder 150 may at least partially expose the associated S/D region 160. For example, at least a portion of the backside of the S/D regions 160 that are not connected to frontside BEOL network 184 may be exposed by the removal of their associated backside contact placeholder 150. Optionally, the exposed S/D region(s) 160 may be at least partially gouged such that a portion of the exposed S/D region 160 by the backside contact openings 220 is removed by a subtractive removal technique, such as an etch.

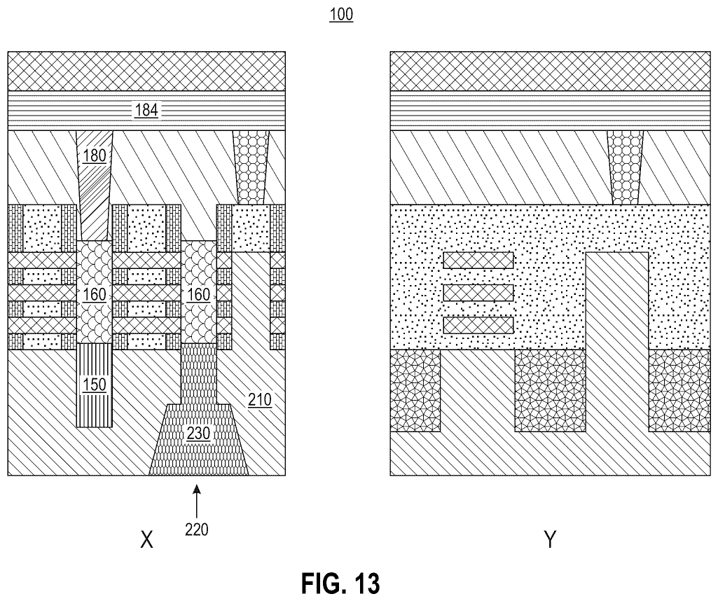

FIG. 13 depicts an fabrication structure cross-section view of the illustrative semiconductor IC device 100 that includes a diffusion break region with gate access inline therewith, according to one or more embodiments of the disclosure. At the present fabrication stage, respective backside contacts 230 may be formed within an associated backside contact opening 220.

The backside contact 230 may be formed within a respective backside contact opening 220 by depositing conductive material, such as metal, therein. In an example, backside contacts 230 may be simultaneously formed by depositing a liner, such as Ni, NiPt or Ti, etc. onto the backside of semiconductor IC device 100 and into the backside contact openings, depositing an adhesion liner, such as TIN, TaN, etc. upon the liner, and by depositing a conductive fill, such as Al, Ru, W, Co, Cu, etc. upon the adhesion liner.

In an example, a backside contact 230 is formed in contact with the associated S/D region 160 that is not connected to frontside BEOL network 184. Further, in these examples, a residual backside contact placeholder 150 maybe located underneath the S/D regions 160 are connected to the frontside BEOL network 184 by a frontside S/D contact 180.

Subsequently, a planarization process, such as a CMP, may expose a bottom surface of the backside ILD 210. As a result, the respective bottom surfaces of backside contacts 230 and backside ILD 210 may be substantially horizontal and/or substantially coplanar.

FIG. 14 depicts an fabrication structure cross-section view of the illustrative semiconductor IC device 100 that includes a diffusion break region with gate access inline therewith, according to one or more embodiments of the disclosure. At the present fabrication stage, backside BEOL network 260 may be formed.

The backside BEOL network 260, such as a backside power distribution network (BSPDN) may be formed upon the backside contacts 230 and upon the backside ILD 210. The backside BEOL network 260 may include signal wires for signal routing and power wires for providing power potential (e.g., VDD, VSS, etc.). The backside BEOL network 260 may allow for the distribution of power wires and signal wires between both the frontside and backside of the semiconductor IC device. The backside BEOL network 260 may further allow for the full or partial decoupling of signal routing and/or power routing and/or allows for dividing or splitting power wires and/or signal wires between both the frontside and backside of the semiconductor IC device. By incorporating the backside BEOL network 260, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 260 may be indirectly electrically and/or indirectly physically connected to the one or more S/D regions 160 by way of a particular backside contact 230. For example, a first backside wire within the backside BEOL network 260 may be electrically connected a first backside contact 230, a second backside wire within the backside BEOL network 260 may be electrically connected to a second different backside contact 230, or the like.

The backside BEOL network 260 can include one or more interconnect dielectric material layers and contains backside conductive wires and/or interconnects, such as VIAs, embedded therein. In some embodiments, the backside wires within the backside BEOL network 260 are composed of Cu. The backside BEOL network 260 can include “x” numbers of backside metal levels, wherein “x” is an integer starting from 1. If not included in frontside BEOL network 184, backside BEOL network 260 may further contain conductive pads that are connected to one or more of the backside metal wires and may be used to connect the semiconductor IC device 100 to the external and/or higher-level structure.

In an example, signal routing and power routing is effectively split between the frontside BEOL network 184 and the backside BEOL network 260. For example, at least 90% of the frontside metal wires (e.g., furthest from the transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires and the remainder backside metal wires which are usually present in metal levels furthest away from the backside contacts, can be used as signal routing wires. Power routing wires may be less dense than signal routing wires. A signal routing wire is defined herein as a conductive feature, such as a wire, interconnect, or the like, that is configured to electrically carry a computational functional or logical potential or signal. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 260 may be a backside power distribution network (BSPDN).

The backside BEOL network 260 includes various wiring levels. The wiring levels may alternate between a VIA level and a metal level. To form a VIA level, an associated dielectric passivation layer may be formed, the dielectric passivation layer may be patterned to create a VIA opening therein, and conductive or metal material may be deposited within the VIA opening to form a via contact.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

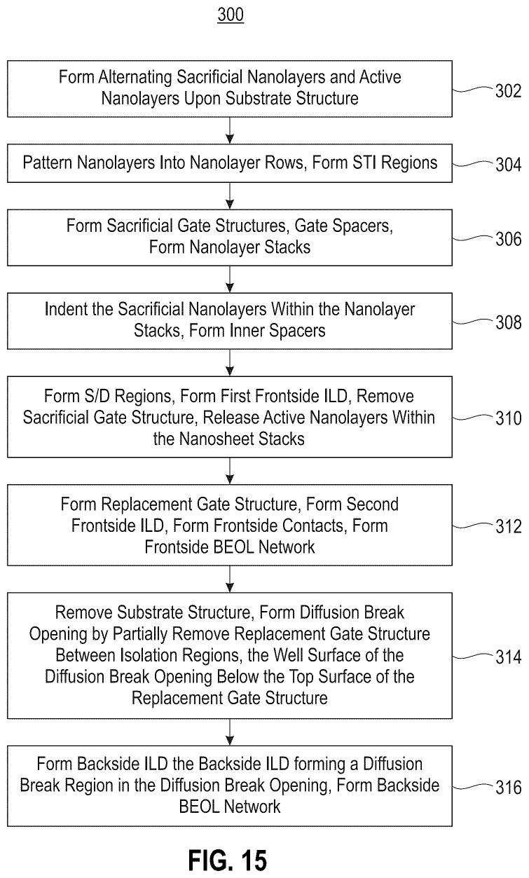

FIG. 15 depicts a flow diagram illustrating a method 300 to fabricate a semiconductor IC device, such as semiconductor IC device 100. The depicted fabrication operations of method 300 are illustratively depicted and described above with reference to one or more of FIG. 4 through FIG. 14 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming alternating sacrificial nanolayers 106 and active nanolayers 108 upon the substrate structure 102. At block 304, method 300 may continue with patterning the nanolayers into nanolayer rows 105 and with forming STI regions 112 between the nanolayer rows 105. At block 306, method may continue with forming sacrificial gate structures 120, with forming gate spacers 130, and with patterning the nanolayer rows 105 into nanolayer stacks 142.

At block 308, method 300 may continue with indenting the sacrificial nanolayers 106 within the nanolayer stacks 142 and with forming inner spacers 146 within the associated void formed by the partial removal of the sacrificial nanolayers 106. At block 310, method 300 may continue with forming backside contact placeholders 150, with forming S/D regions 160, with forming ILD 164, with removing sacrificial gate structures 120, and with releasing the active nanolayers 108 within the nanosheet stacks 142 by removing the sacrificial nanolayers 106.

At block 312, method 300 may continue with forming the respective replacement gate structure 170 within the opening formed by the removal of the sacrificial gate structure 120. Further, at block 312, method 300 may continue with forming ILD 174, with forming frontside contacts 180, 182, and with forming frontside BEOL network 184.

At block 314 method 300 may continue with removing the substrate structure 102, with forming diffusion break opening 202 by partially removing the associated replacement gate structure 170 between STI regions 112. The well surface of the diffusion break opening 202 is below the top surface of the replacement gate structure 170, so as to form portion 204 of the replacement gate structure 170 between the diffusion break opening 202 and the frontside contact ILD(s). At block 316, method 300 may continue with forming backside ILD 210, with forming backside contacts 230, and with forming backside BEOL network 260.

In a particular example, method 300 includes forming a diffusion break opening by removing a replacement gate and active semiconductor nanolayers from a backside of the semiconductor IC device, wherein a well surface of the diffusion break opening is below an upper surface of the replacement gate. Method 300 further includes forming a diffusion break region by depositing a diffusion break dielectric within the diffusion break opening and forming a frontside gate contact in direct contact with the replacement gate located above and inset within the diffusion break region.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
an active region comprising a plurality of channels;
a diffusion break region;
a gate in direct contact with each of the plurality of channels and wrapped around the diffusion break region; and
a frontside gate contact in direct contact with the gate and above and inset within the diffusion break region.

2. The semiconductor IC device of claim 1, wherein the diffusion break region comprises a backside interlayer dielectric (ILD).

3. The semiconductor IC device of claim 2, wherein the backside ILD is directly connected to a plurality of faux channels.

4. The semiconductor IC device of claim 3, wherein a top surface of the backside ILD is between a top surface of a topmost channel of the plurality of channels and a top surface of the gate.

5. The semiconductor IC device of claim 3, wherein a top surface of the backside ILD is substantially coplanar with a top surface of a topmost channel of the plurality of channels.

6. The semiconductor IC device of claim 3, wherein charge carriers do not flow through the plurality of faux channels.

7. The semiconductor IC device of claim 6, further comprising:
a source/drain (S/D) region in direct contact with the plurality of faux channels; and
a backside contact in direct contact with the S/D region and in direct contact with the backside ILD.

8. The semiconductor IC device of claim 7, further comprising:
a frontside back end of line (BEOL) network directly connected to the frontside gate contact; and
a backside BEOL network direct connected to the backside contact.

9. The semiconductor IC device of claim 8, further comprising:
a shallow trench isolation (STI) region below the gate and between the active region and the diffusion break region.

10. The semiconductor IC device of claim 9, further comprising:
a first inner spacer between faux channels of the plurality of faux channels, in direct contact with the backside ILD, and in direct contact with the S/D region.

11. A semiconductor integrated circuit (IC) device comprising:
an isolation region between an adjacent first transistor cell and second transistor cell, the first transistor cell comprising a first plurality of channels, and the second transistor cell comprising a diffusion break region;
a first gate in direct contact with each of the first plurality of channels and wrapped around the diffusion break region;
a frontside gate contact in direct contact with the first gate and above and inset within the diffusion break region; and
a transistor comprising: a second plurality of channels between a first source/drain (S/D) region and a second S/D region and a second gate in direct contact with each of the second plurality of channels.

12. The semiconductor IC device of claim 11, wherein the diffusion break region comprises a backside interlayer dielectric (ILD).

13. The semiconductor IC device of claim 12, wherein the backside ILD is directly connected to a plurality of faux channels.

14. The semiconductor IC device of claim 13, wherein a top surface of the backside ILD is between a top surface of a topmost channel of the first plurality of channels and a top surface of the first gate.

15. The semiconductor IC device of claim 13, wherein a top surface of the backside ILD is substantially coplanar with a top surface of a topmost channel of the first plurality of channels.

16. The semiconductor IC device of claim 13, wherein charge carriers do not flow through the plurality of faux channels.

17. The semiconductor IC device of claim 16, further comprising:
a backside contact in direct contact with the first S/D region and in direct contact with the backside ILD; and
a frontside contact in direct contact with the second S/D region.

18. The semiconductor IC device of claim 17, further comprising:
a frontside back end of line (BEOL) network directly connected to the frontside gate contact and directly connected to the frontside contact; and
a backside BEOL network direct connected to the backside contact.

19. The semiconductor IC device of claim 11, wherein the plurality of faux channels are each directly connected to the first S/D region.

20. A semiconductor integrated circuit (IC) device fabrication method comprising:
forming a diffusion break opening by removing a replacement gate and active semiconductor nanolayers from a backside of the semiconductor IC device, wherein a well surface of the diffusion break opening is below an upper surface of the replacement gate;
forming a diffusion break region by depositing a diffusion break dielectric within the diffusion break opening; and
forming a frontside gate contact in direct contact with the replacement gate located above and inset within the diffusion break region.
